(19) United States
(12) Patent Application Publication
(10) Pub. No.: US 2025/0329570 A1
(43) Pub. Date: Oct. 23, 2025

(54) WAFER TRANSFER APPARATUS

(71) Applicant: Samsung Electronics Co., Ltd., Suwon-si (KR)

(72) Inventors: Younsu HA, Suwon-si (KR); Donghoon KWON, Suwon-si (KR)

(73) Assignee: Samsung Electronics Co., Ltd., Suwon-si (KR)

(21) Appl. No.: 18/903,085

(22) Filed: Oct. 1, 2024

(30) Foreign Application Priority Data
Apr. 22, 2024 (KR) 10-2024-0053272

(51) Int. Cl. H01L 21/687; B24B 41/00; B25J 11/00; B25J 15/00

(52) U.S. Cl. CPC H01L 21/68707; B24B 41/005; B25J 11/0095; B25J 15/0014

(57) ABSTRACT

The present inventive concepts provide a wafer transfer apparatus. The wafer transfer apparatus according to an example embodiment of the present inventive concepts includes a transfer arm configured to transfer a wafer, a blade coupled to an end portion of the transfer arm and configured to support the wafer, and a light irradiation unit on the blade and configured to irradiate ultraviolet light toward the wafer.

### CROSS-REFERENCE TO RELATED APPLICATION(S)

This application claims benefit of priority to Korean Patent Application No. 10-2024-0053272, filed on Apr. 22, 2024 in the Korean Intellectual Property Office, the inventive concepts of which is incorporated herein by reference in its entirety.

### BACKGROUND

The present inventive concepts relate to a wafer transfer apparatus.

In general, a semiconductor device is manufactured by repetitively performing unit processes such as deposition, photolithography, etching, polishing, cleaning, drying, and the like. Among the unit processes, the polishing process may planarize a surface of the wafer by polishing the surface of the wafer for performing the subsequent photolithography process.

Through chemical mechanical polishing (CMP), one of the planarization methods in the polishing process, by supplying a polishing slurry to a surface of a polishing pad, the surface of the wafer may be polished while the wafer is disposed between the polishing pad and a carrier head pressing the wafer, and the polishing pad and the carrier head rotate. Due to the characteristics of this chemical mechanical polishing process using the polishing slurry, it is possible to improve a polishing speed by forming a surface of a film on the wafer to be hydrophilic.

### SUMMARY

Various example embodiments of the present inventive concepts are to provide a wafer transfer apparatus that can enhance hydrophilic treatment on a surface of the wafer.

According to various example embodiments of the present inventive concepts, a wafer transfer apparatus may include a transfer arm configured to transfer a wafer, a blade coupled to an end portion of the transfer arm and configured to support the wafer, and a light irradiation unit on the blade and configured to irradiate ultraviolet light toward the wafer.

According to various example embodiments of the present inventive concepts, a wafer transfer apparatus may include a transfer arm configured to transfer a wafer, a blade coupled to an end portion of the transfer arm, the blade configured to support the wafer on a first surface of the blade, and the blade comprised of a light-transmitting material, and a light irradiation unit on a second surface of the blade opposite to the first surface of the blade and configured to irradiate ultraviolet light toward the wafer.

According to various example embodiments of the present inventive concepts, a wafer transfer apparatus may include a transfer arm configured to transfer a wafer to a polishing position within a polishing apparatus, a driving unit configured to drive an operation of the transfer arm, a blade coupled to an end portion of the transfer arm and configured to support the wafer, and a light irradiation unit on the blade and configured to irradiate ultraviolet light toward the wafer while the wafer is being transferred to the polishing position by the transfer arm.

### BRIEF DESCRIPTION OF DRAWINGS

The above and other aspects, features, and advantages of various example embodiments will be more clearly understood from the following detailed description, taken in conjunction with the accompanying drawings:

FIG. 1 is a diagram of a polishing apparatus and a wafer transfer apparatus according to various example embodiments of the present inventive concepts;

FIG. 2 is a diagram of a wafer transfer apparatus according to various example embodiments of the present inventive concepts;

FIG. 3 is a cross-sectional view of portion A-A′ of FIG. 2;

FIG. 4 is a cross-sectional view of portion A-A′ of FIG. 2; according to various example embodiments;

FIG. 5 is a cross-sectional view of portion A-A′ of FIG. 2 according to various example embodiments;

FIG. 6 is a cross-sectional view of portion A-A′ of FIG. 2 according to various example embodiments;

FIG. 7 is a cross-sectional view of portion A-A′ of FIG. 2 according to various example embodiments;

FIG. 8 is a cross-sectional view of portion A-A′ of FIG. 2 according various example embodiments;

FIG. 9 is a cross-sectional view of portion A-A′ of FIG. 2 according to various example embodiments;

FIG. 10 is a cross-sectional view of portion A-A′ of FIG. 2 according various example embodiments;

FIG. 11 is a diagram illustrating a coupling portion between an end portion of the transfer arm and one end of the blade according to various example embodiments of the present inventive concepts;

FIG. 12 is a diagram illustrating a coupling portion between an end portion of the transfer arm and one end of the blade according to various example embodiments of the present inventive concepts;

FIG. 13 is a diagram illustrating a coupling portion between an end portion of the transfer arm and one end of the blade according to various example embodiments of the present inventive concepts;

FIG. 14 is a diagram illustrating a coupling portion between an end portion of the transfer arm and one end of the blade according to various example embodiments of the present inventive concepts;

FIG. 15 is a diagram illustrating a structure in which an end portion of the transfer arm and one end of the blade are integrally formed according to various example embodiments of the present inventive concepts;

FIG. 16 is a diagram of a wafer transfer apparatus according to various example embodiments of the present inventive concepts;

FIG. 17 is a diagram of a wafer transfer apparatus according to various example embodiments of the present inventive concepts;

FIG. 18 is a diagram of a wafer transfer apparatus according to various example embodiments of the present inventive concepts;

FIG. 19 is a diagram of a wafer transfer apparatus according to various example embodiments of the present inventive concepts;

FIG. 20 is a diagram of a wafer transfer apparatus according to various example embodiments of the present inventive concepts;

FIG. 21 is a plan view of a wafer transfer apparatus according to various example embodiments of the present inventive concepts; and

FIG. 22 is an diagram of a wafer transfer apparatus according to various example embodiments of the present inventive concepts.

### DETAILED DESCRIPTION

Hereinafter, preferred example embodiments of the present inventive concepts will be described with reference to the attached drawings.

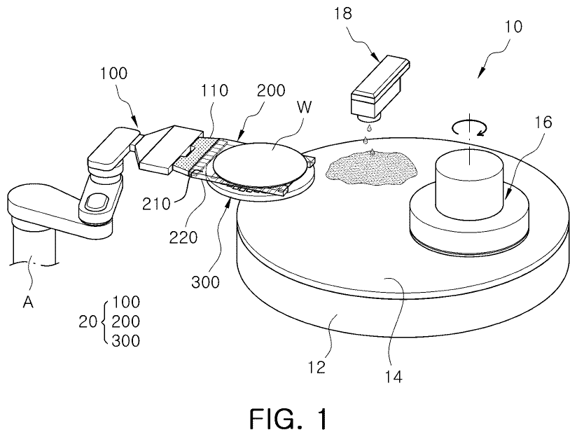

FIG. 1 is an diagram of a polishing apparatus and a wafer transfer apparatus according to various example embodiments of the present inventive concepts.

The wafer transfer apparatus according to various example embodiments of the present inventive concepts may be used to transfer a wafer in various wafer processing processes. In various example embodiments, as shown in FIG. 1, it can be applied as a wafer transfer apparatus 20 transferring the wafer W to a polishing position of a polishing apparatus 10 in the polishing process, to be described in detail below.

Referring to FIG. 1, the polishing apparatus 10 according to various example embodiments may be a chemical mechanical polishing apparatus and may include a platen 12, a polishing pad 14, a polishing head 16, and a slurry supply unit 18.

The platen 12 may be rotatably installed on a rotation axis (not shown), and an upper end portion thereof may have a circular plate shape. The platen 12 may be rotated in a certain direction. In addition, a polishing pad 120 may be installed on an upper surface of the platen 12.

The polishing pad 14 may be provided with a polishing layer (not shown) on the upper surface for polishing the wafer W.

The polishing head 16 may be disposed above the platen 12 and contact the wafer into the polishing pad 14. In addition, the polishing head 16 may be rotated in a certain direction. Accordingly, the wafer W mounted on the bottom of the polishing head 16 may be in contact with the polishing pad 14 while the wafer W is rotated on the polishing pad 14. As described above, mechanical polishing may be performed while the wafer W is in contact with the polishing pad 14. Meanwhile, although only one polishing head 16 is shown in FIG. 1, a plurality of polishing heads may be provided to hold additional wafers so that a surface area of the polishing pad 14 can be more efficiently used.

The slurry supply unit 18 may supply slurry to the polishing pad 14. Accordingly, slurry S supplied from the slurry supply unit 140 may be provided to the polishing head 16. Meanwhile, when the CMP process is performed, chemical and mechanical polishing of the wafer W may be performed using the slurry S supplied from the slurry supply unit 18.

The wafer transfer apparatus 20 according to various example embodiments of the present inventive concepts may include a transfer arm 100, a driving unit (A), a blade 200, and a light irradiation unit 300.

The transfer arm 100 may transfer the wafer W to a polishing position within the polishing apparatus 10. As an example, the transfer arm 100 may transfer the wafer W to the polishing position of the polishing pad 14 of the polishing apparatus 10, and accordingly, polishing may be performed while the wafer W is positioned between the polishing pad 14 and the polishing head 16. The transfer arm 100 may be configured in multiple stages, and may be configured to perform at least one of a lifting operation, a horizontal movement, and a rotation operation as needed. The operation of the transfer arm 100 may be driven by the driving unit (A). The driving unit (A) may include a driving motor, and the like.

The blade 200 may be coupled to an end portion 110 of the transfer arm 100 and can support the wafer W. The blade 200 may include one surface 210 supporting the wafer W and the other surface 220 opposite to the one surface 210. A light irradiation unit 300 irradiating ultraviolet light toward the wafer W may be disposed on the blade 200. The blade 200 may be implemented in various example embodiments depending on a dispositional position of the light irradiation unit 300, which will be described later.

The light irradiation unit 300 may be disposed on the blade 200 in various dispositional forms and may irradiate ultraviolet light toward the wafer W before the wafer W is positioned in the polishing position of the polishing apparatus 10. In various example embodiments, the light irradiation unit 300 may irradiate ultraviolet light toward the wafer W while the wafer W is being transferred to the polishing position of the polishing apparatus 10 by the transfer arm 100. Accordingly, hydrophilic treatment on a surface of the wafer W may be enhanced by oxidizing or hardening the surface of the wafer W by irradiating ultraviolet light before the surface of the wafer W is polished. A polishing speed may be effectively improved when polishing the surface of the wafer W with the enhanced hydrophilic treatment, and as an example, the polishing speed can be effectively improved when polishing a carbon-based hydrophobic film.

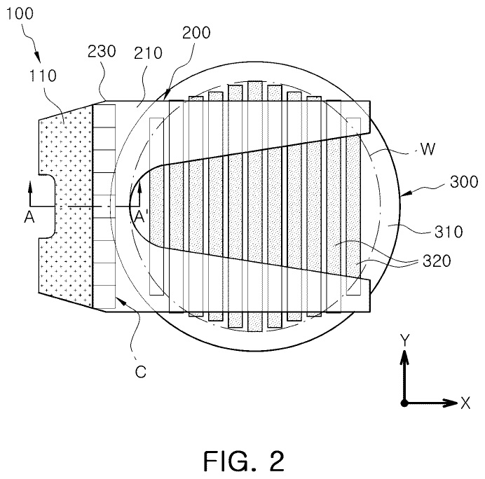

In various example embodiments, the light irradiation unit 300 may be disposed on the other surface 220 of the blade 200. The light irradiation unit 300 may have an irradiation range irradiating ultraviolet light toward an entire region of the wafer W. In this case, at least a portion of the blade 200 may have a light transmitting region through which ultraviolet light irradiated by the light irradiation unit 300 passes. In various example embodiments, the light transmitting region of the blade 200 may be configured so that an irradiation area of the ultraviolet light irradiated by the light irradiation unit 300 is equal to the size of the wafer W or greater than the size of the wafer W so as to cover the entire surface of the wafer W. As shown in FIG. 2, the blade 200 may be entirely formed of a light-transmitting material. As an example, the blade 200 may include one of acrylic polymer, silicone polymer, quartz, and fumed silica.

However, the present inventive concepts are not limited thereto, and the blade may be formed entirely of an opaque material depending on a dispositional position of the blade in which the light irradiation unit is disposed in various dispositional forms, which will be described later.

Meanwhile, the light irradiation unit 300 may include one or a plurality of ultraviolet light-emitting diode lamps 320. Referring to FIGS. 1 and 2, the light irradiation unit 300 may include a main body 310 disposed on the other surface 220 of the blade 200, and a plurality of ultraviolet light-emitting diode lamps 320 disposed on the main body 310. In various example embodiments, as shown in FIG. 2, the main body 310 may be configured in various forms, such as a disk shape having a size larger than the size of the wafer W. The plurality of ultraviolet light-emitting diode lamps 320 may be disposed in various forms within the main body 310. As an example, the light irradiation unit 300 may include a plurality of ultraviolet light-emitting diode lamps 320 disposed to be spaced apart from each other in a first direction (X) of the blade 200. In various example embodiments, the plurality of ultraviolet light-emitting diode lamps 320 may respectively extend in a second direction (Y), perpendicular to the first direction (X) of the blade 200. Here, as shown in FIGS. 1 and 2, the first direction (X) of the blade 200 may be a longitudinal direction of the blade 200, and the second direction (Y) of the blade 200 may be a width direction of the blade 200.

The plurality of ultraviolet light-emitting diode lamps 320 may be configured so that an extension length extended in the second direction (Y) of the blade 200 to correspond to the shape of the wafer W is shorter from a central portion to both side portions of the blade 200 when viewed in the first direction (X) of the blade 200. Accordingly, ultraviolet light can be irradiated toward an entire region of the wafer W by the plurality of ultraviolet light-emitting diode lamps 320. However, a dispositional form of the ultraviolet light-emitting diode lamp in various example embodiments is not limited thereto and can be variously implemented according to actual needs, which will be described later.

The blade 200 may be coupled to the transfer arm 100 in various methods. In various example embodiments, as shown in FIG. 2, a coupling portion C between one end 230 of the blade 200 and an end portion 110 of the transfer arm 100 may have a coupling structure extending across a width direction (the second direction (Y) of the blade 200) of the transfer arm 100 and the blade 200 in a straight-line form.

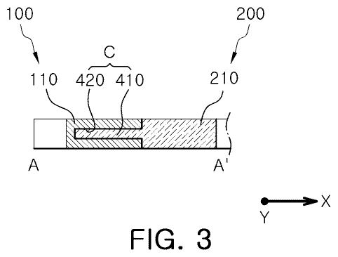

In various example embodiments, the coupling portion C between the end 230 of the blade 200 and the end portion 110 of the transfer arm 100 may have a fitting coupling structure. For example, as shown in FIG. 3, one coupling protrusion 410 may be disposed at the end portion 110 of the transfer arm 100, and one coupling groove 420 into which the coupling protrusion 410 is inserted may be disposed at the one end 230 of the blade 200. The coupling protrusion 410 may be formed to protrude from a portion located between upper and lower ends at the end portion 110 of the transfer arm 100, and the coupling groove 420 may be formed to be recessed in a portion located between the upper and lower ends at the one end 230 of the blade 200. The coupling portion C between the one end 230 of the blade 200 and the end portion 110 of the transfer arm 100 may have three coupling steps. A coupling length of the coupling protrusion 410 and the coupling groove 420 may be formed to be long in the first direction (X) of the blade 200 for stable coupling. Accordingly, the one end 230 of the blade 200 and the end portion 110 of the transfer arm 100 may be integrally coupled through the coupling structure of the coupling protrusion 410 and the coupling groove 420.

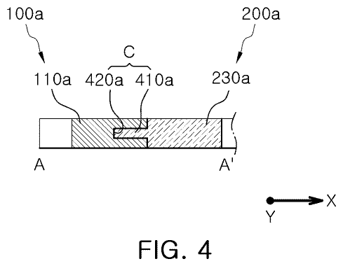

However, the present inventive concepts are not limited thereto and may have a coupling structure having various forms. With regard thereto, various example embodiments will be described below with reference to FIGS. 4 to 10.

FIG. 4 is an cross-sectional view of portion A-A′ of FIG. 2 according to various example embodiments.

Referring to FIG. 4, one coupling protrusion 410a may be disposed at an end portion 110a of the transfer arm 100a, and one coupling groove 420a into which the coupling protrusion 410a is inserted may be disposed at one end 230a of the blade 200a. Accordingly, three coupling steps may be formed in a coupling portion C between the one end 230a of the blade 200a and the end portion 110a of the transfer arm 100a. A coupling length of the coupling protrusion 410a and the coupling groove 420a may be configured to be shorter than the coupling length of the coupling protrusion 410 and the coupling groove 420 in the first direction (X) of the blade 200a according to various example embodiments.

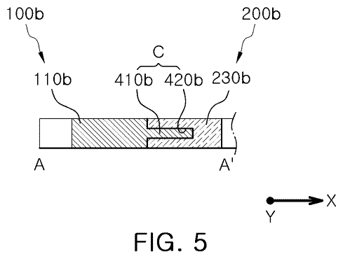

FIG. 5 is an cross-sectional view of portion A-A′ of FIG. 2 according to various example embodiments.

Referring to FIG. 5, one coupling protrusion 410b may be disposed at an end portion 110b of the transfer arm 100b, and the one coupling protrusion 410b may be inserted into the coupling groove 420b disposed at one end 230b of the blade 200b. Accordingly, three coupling steps may be formed in a coupling portion C between the one end 230b of the blade 200b and the end portion 110b of the transfer arm 100b. A coupling length of the coupling protrusion 410b and the coupling groove 420b may be configured to be shorter than the coupling length of the coupling protrusion 410 and the coupling groove 420, as seen in various example embodiments with respect to FIG. 3, in the first direction (X) of the blade 200b.

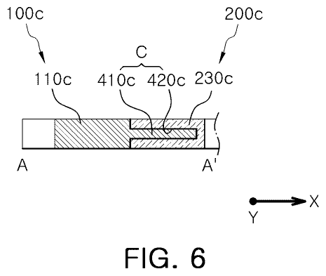

FIG. 6 is an cross-sectional view of portion A-A′ of FIG. 2 according to various example embodiments.

Referring to FIG. 6, one coupling groove 420c may be disposed at an end portion 110c of the transfer arm 100c, and one coupling protrusion 410c inserted into the coupling groove 420c may be disposed at one end 230c of the blade 200c. Accordingly, three coupling steps may be formed in a coupling portion C between the one end 230c of the blade 200c and the end portion 110c of the transfer arm 100c. A coupling length of the coupling protrusion 410c and the coupling groove 420c may be configured to be the same as the coupling length of the coupling protrusion 410 and the coupling groove 420 in the first direction (X) of the blade 200c according to various example embodiments, but the present inventive concepts are not limited thereto, and the coupling length thereof may be configured to be longer or shorter than the coupling length of the coupling protrusion 410 and the coupling groove 420 in Example 1.

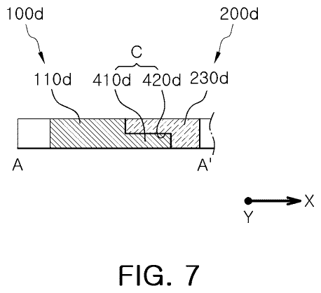

FIG. 7 is an cross-sectional view of portion A-A′ of FIG. 2 according to various example embodiments.

Referring to FIG. 7, one coupling protrusion 410d may be disposed at an end portion 110d of the transfer arm 100d, and one coupling protrusion 410d inserted into the coupling groove 420d may be disposed at one end 230d of the blade 200d. The coupling protrusion 410d may be formed to protrude from a lower end portion of the end portion 110d of the transfer arm 100d, and the coupling groove 420d may be formed to be recessed in the lower end portion of the one end 230d of the blade 200d. Accordingly, two coupling steps may be formed in a coupling portion C between the one end 230d of the blade 200d and the end portion 110d of the transfer arm 100d. In this case, the coupling portion C between the one end 230d of the blade 200d and the end portion 110d of the transfer arm 100d may be adhered using an adhesive or integrally coupled using a fastening member such as fastening bolts, or the like, as needed.

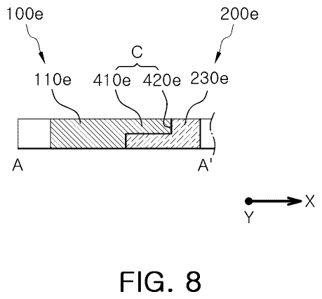

FIG. 8 is a cross-sectional view of portion A-A′ of FIG. 2 according to various example embodiments.

Referring to FIG. 8, one coupling protrusion 410e may be disposed at an end portion 110e of the transfer arm 100e, and one coupling groove 420e into which the coupling protrusion 410e is inserted may be disposed at one end 230e of the blade 200e. The coupling protrusion 410e may be formed to protrude from an upper end portion of the end portion 110e of the transfer arm 100e, and the coupling groove 420e may be formed to be recessed in the upper end portion of the one end 230e of the blade 200e. Accordingly, two coupling steps may be formed in a coupling portion C between the one end 230e of the blade 200e and the end portion 110e of the transfer arm 100e. In this case, the coupling portion C between the one end 230e of the blade 200e and the end portion 110e of the transfer arm 100e may be adhered using an adhesive or integrally coupled using a fastening member such as fastening bolts, or the like, as needed.

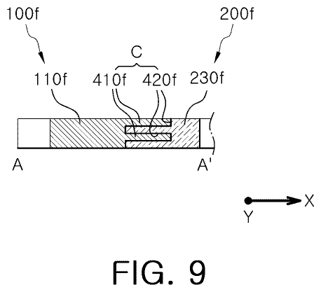

FIG. 9 is a cross-sectional view of portion A-A′ of FIG. 2 according to various example embodiments.

Referring to FIG. 9, two coupling protrusions 410f may be disposed at an end portion 110f of the transfer arm 100f, and two coupling grooves 420f into which each of the coupling protrusions 410f is inserted may be disposed at one end 230f of the blade 200f. The two coupling protrusions 410f may be spaced apart from each other and may be formed to protrude from an upper end portion of the end portion 110f of the transfer arm 100f and a portion between the upper and lower ends thereof, respectively, and the two coupling grooves 420f may be formed to be recessed in the upper end portion of the one end 230f of the transfer arm 100f and a portion between the upper and lower ends thereof, respectively. Accordingly, four coupling steps may be formed in a coupling portion C between the one end 230f of the blade 200f and the end portion 110f of the transfer arm 100f. The one end 230f of the blade 200f and the end portion 110f of the transfer arm 100f may be integrally coupled through a fitting coupling structure of the coupling protrusion 410f and the coupling groove 420f.

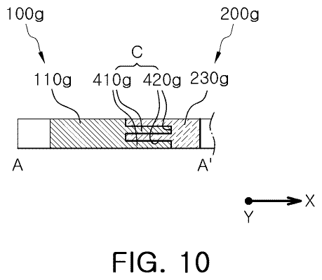

FIG. 10 is an cross-sectional view of portion A-A′ of FIG. 2 according to various example embodiments.

Referring to FIG. 10, two coupling protrusions 410g may be disposed at an end portion 110g of the transfer arm 100g, and two coupling grooves 420g into which each of the coupling protrusions 410g is inserted may be disposed at one end 230g of the blade 200g. The two coupling protrusions 410g may be spaced apart from each other and may be formed to protrude from a portion between upper and lower ends of the end portion 110g of the transfer arm 100g and a lower end portion thereof, respectively, and the two coupling grooves 420g may be formed to be recessed in a portion between the upper and lower ends of one end 230g of the blade 200g and in the lower end portion thereof, respectively. Accordingly, four coupling steps may be formed in a coupling portion C between the one end 230g of the blade 200g and the end portion 110g of the transfer arm 100g. The one end 230g of the blade 200g and the end portion 110g of the transfer arm 100g may be integrally coupled through a fitting coupling structure of the coupling protrusion 410g and the coupling groove 420g.

In the above-described various example embodiments, a structure in which the coupling portion of one end of the blade and an end portion of the transfer arm is integrally coupled through a fitting coupling structure between the coupling protrusion and the coupling groove has been described, but the present inventive concepts are not limited thereto, various coupling structures using an adhesive method, a fastening member, or the like, may be applied. In addition, the shape and number of the coupling protrusions and coupling grooves are not particularly limited in the present inventive concepts, and three or more coupling protrusions and coupling grooves may be provided, depending on the specific shape and need.

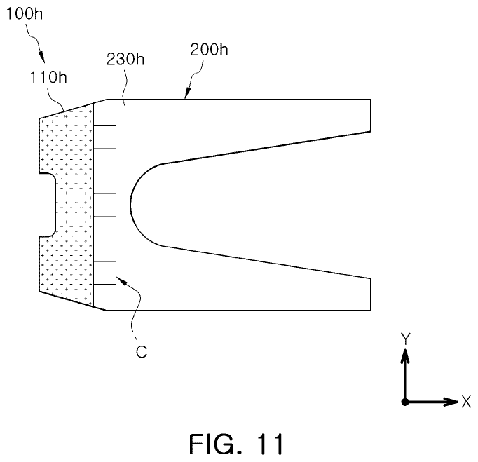

Meanwhile, in various example embodiments described above, the coupling portion C between the one end 230 of the blade 200 and the end portion 110 of the transfer arm 100 has been described in a form having a coupling structure extending across the width direction (second direction (Y) of the blade 200) of the transfer arm 100 and the blade 200 in the form of a straight line, but the present inventive concepts are not limited thereto, and may be implemented in various forms. With regard thereto, various example embodiments of the inventive concepts will be described below with reference to FIGS. 11 to 15.

FIG. 11 a diagram illustrating a coupling portion between an end portion of the transfer arm and one end of the blade according to various example embodiments of the present inventive concepts.

Referring to FIG. 11, the coupling portion C between one end 230h of the blade 200h and an end portion 110h of the transfer arm 100h may have a plurality of coupling structures spaced apart and arranged in the second direction (Y) of the blade 200h. Regarding the above-described coupling structure, any one coupling structure in the various example embodiments may be applied, and no redundant explanation will be given.

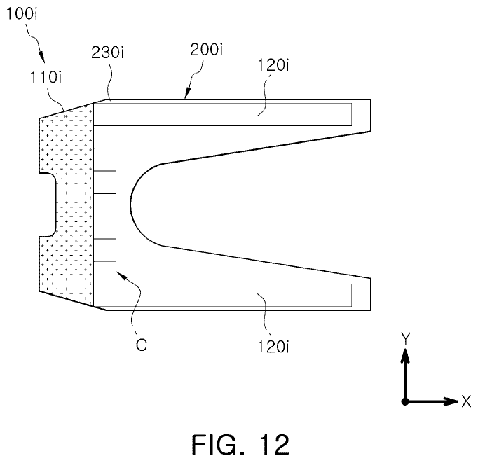

FIG. 12 is a diagram illustrating a coupling portion between an end portion of the transfer arm and one end of the blade according to various example embodiments of the present inventive concepts.

Referring to FIG. 12, the coupling portion C between one end 230i of the blade 200i and an end portion 110i of the transfer arm 100i may have a coupling structure extending across a width direction (second direction (Y) of the blade 200i) of the transfer arm 100i and the blade 200i in the form of a straight line. Furthermore, both side portions in the second direction (Y) of the blade 200i from the end portion 110i of the transfer arm 100i may further include a guide beam 120i extending in the longitudinal direction (the first direction (X) of the blade 200i) of the blade 200i. The guide beam 120i may be inserted into the blade 200i to achieve a stable coupling structure with the blade 200i.

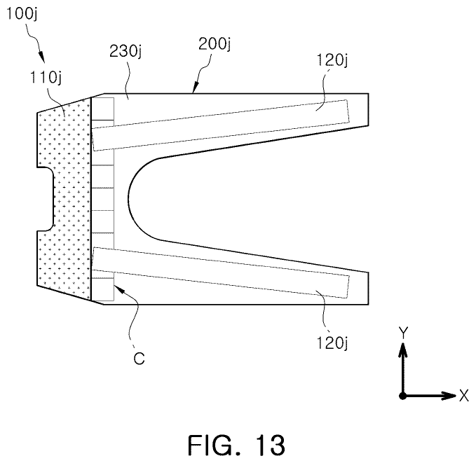

FIG. 13 is a diagram illustrating a coupling portion between an end portion the transfer arm and one end of the blade according to various example embodiments of the present inventive concepts.

Referring to FIG. 13, the coupling portion C between one end 230j of the blade 200j and an end portion 110j of the transfer arm 100j may have a coupling structure extending across a width direction (second direction (Y) of the blade 200j) of the transfer arm 100j and the blade 200j in the form of a straight line. Furthermore, both side portions in the second direction (Y) of the blade 200j from the end portion 110j of the transfer arm 100j may further include a guide beam 120j extending in the longitudinal direction of the blade 200j (a direction inclined at a certain angle with respect to the first direction (X) of the blade 200j). The guide beam 120j may be inserted into the blade 200j to achieve a stable coupling structure with the blade 200j.

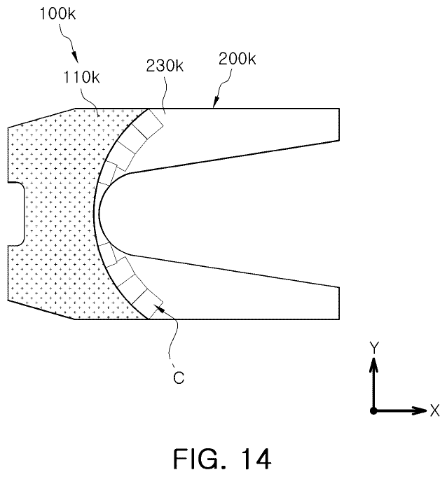

FIG. 14 is an diagram illustrating a coupling portion between an end portion the transfer arm and one end of the blade according to various example embodiments of the present inventive concepts.

Referring to FIG. 14, a coupling portion C between one end 230k of the blade 200k and an end portion 110k of the transfer arm 100k may have a coupling structure extending across a width direction of the transfer arm 100k and the blade 200k in a curved shape. The coupling portion C between the one end 230k of the blade 200k and the end portion 110k of the transfer arm 100k may have a curved shape corresponding to a curved shape of the wafer. Regarding the above-described coupling structure, any one coupling structure in Example 1 and Modified Examples 1 to 7 can be applied, and no redundant explanation will be given.

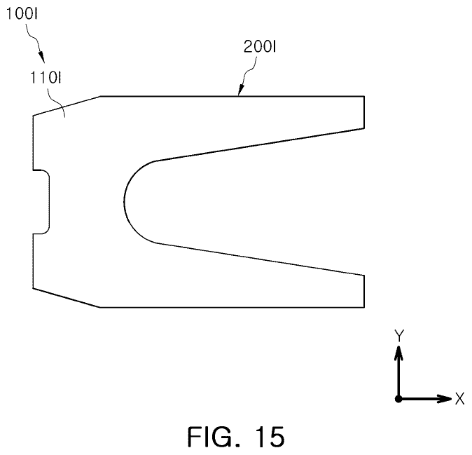

FIG. 15 is a diagram illustrating a structure in which an end portion the transfer arm and one end of the blade according to various example embodiments of the present inventive concepts.

Referring to FIG. 15, a blade 2001 and an end portion 1101 of the transfer arm 1001 may be integrally formed, and in this case, the blade 200 may be entirely formed of a light transmitting material. However, the present inventive concepts are not limited thereto, and the blade may be formed of an opaque material depending on a position in which the light irradiation unit is disposed on the blade.

Meanwhile, in various example embodiments as described above, it is illustrated that the plurality of ultraviolet light-emitting diode lamps 320 are configured so that an extension length extending in the second direction (Y) of the blade 200 becomes shorter from a central portion to both side portions when viewed in the first direction (X) of the blade 200, so as to correspond to the shape of the wafer W, but the present inventive concepts are not limited thereto, and will be described in more detail below.

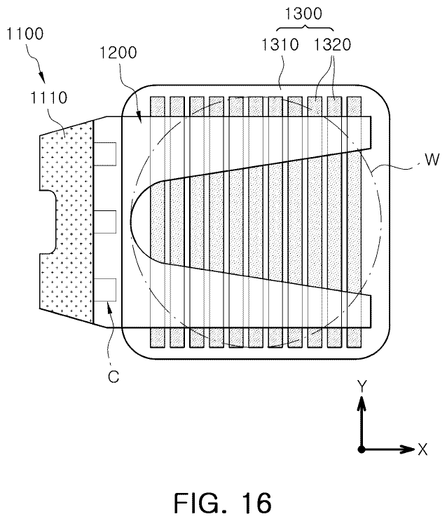

FIG. 16 is a diagram of a wafer transfer apparatus according to various example embodiments of the present inventive concepts.

Referring to FIG. 16, the wafer transfer apparatus may include a transfer arm 1100, a blade 1200 coupled to the end portion 1110 of the transfer arm 1100, and a light irradiation unit 1300 disposed on the blade 1200. The configuration of the transfer arm 1100 and the blade 1200 may be implemented in any one of the above-described example embodiments, and no redundant descriptions thereof will be omitted.

The light irradiation unit 1300 may include a main body 1310 disposed on the other surface of the blade 1200 and a plurality of ultraviolet light-emitting diode lamps 1320 disposed on the main body 1310. As shown in FIG. 16, the main body 1310 may be configured in the form of a square plate having a size larger than the size of the wafer W. The plurality of ultraviolet light-emitting diode lamps 1320 may be disposed in various forms inside the main body 1310. The light irradiation unit 1300 may include a plurality of ultraviolet light-emitting diode lamps 1320 disposed to be spaced apart from each other in a first direction (X) of the blade 1200. In various example embodiments, the plurality of ultraviolet light-emitting diode lamps 1320 may respectively extend in a second direction (Y) perpendicular to the first direction (X) of the blade 1200. The plurality of ultraviolet light-emitting diode lamps 1320 may be configured to have the same extension length in the second direction (Y) of the blade 1200 to correspond to the shape of the wafer W. Accordingly, ultraviolet light can be irradiated toward the entire region of the wafer W by the plurality of ultraviolet light-emitting diode lamps 1320.

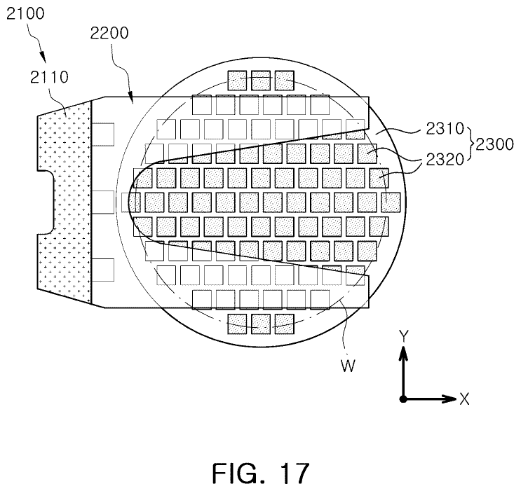

FIG. 17 is a diagram of a wafer transfer apparatus according to various example embodiments of the present inventive concepts.

Referring to FIG. 17, the wafer transfer apparatus may include a transfer arm 2100, a blade 2200 coupled to an end portion 2110 of the transfer arm 2100, and a light irradiation unit 2300 disposed on the blade 2200. The configuration of the transfer arm 2100 and the blade 2200 may be implemented in any one of the above-described example embodiments, and no redundant description thereof will be omitted.

The light irradiation unit 2300 may include a main body 2310 disposed on the other surface of the blade 2200 and a plurality of ultraviolet light-emitting diode lamps 2320 disposed on the main body 2310. In various example embodiments, as shown in FIG. 17, the main body 2310 may be configured in the form of a disk having a size larger than the size of the wafer W. The plurality of ultraviolet light-emitting diode lamps 2320 may be disposed in various forms inside the main body 2310. The light irradiation unit 2300 may include a plurality of ultraviolet light-emitting diode lamps 2320 disposed to be spaced apart from each other in a first direction (X) of the blade 2200 and a third direction different from the first direction (X). Here, the third direction of the blade 2200 may be various directions. For example, the third direction may be a second direction (Y) perpendicular to the first direction (X) of the blade 2200 or any direction between the first direction (X) and the second direction (Y), and the third direction of the blade 2200 is not particularly limited as long as it can irradiate ultraviolet light uniformly throughout the wafer. As another example, a plurality of ultraviolet light-emitting diode lamps may be randomly disposed to be spaced at regular intervals within the main body.

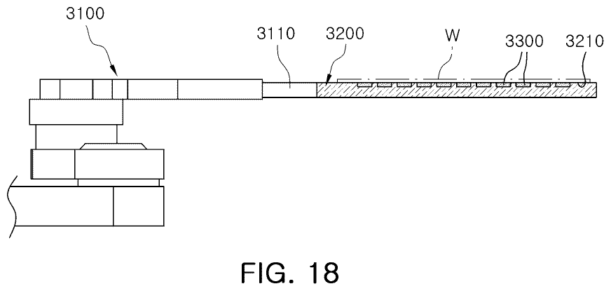

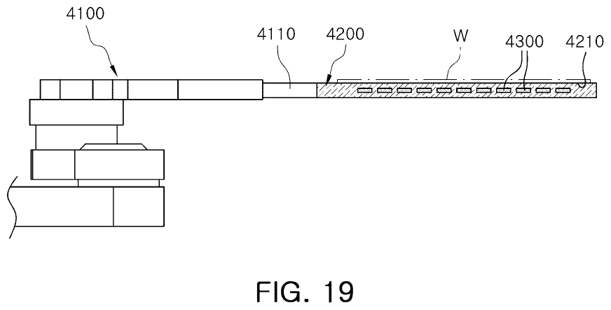

In the above-described various example embodiments, the light irradiation unit has been described as being disposed on the other surface of the blade, but the present inventive concepts are not limited thereto, and light irradiation units disposed at various positions of the blade will be described through various example embodiments with reference to FIGS. 18 and 19.

FIG. 18 is a diagram of a wafer transfer apparatus according to various example embodiments of the present inventive concepts.

Referring to FIG. 18, the wafer transfer apparatus may include a transfer arm 3100, a blade 3200 coupled to an end portion 3110 of the transfer arm 3100, and a light irradiation unit 3300 disposed on the blade 3200. The configuration of the transfer arm 3100 and the blade 3200 may be implemented in any one of the above-described Example 1 and the above-described example embodiments, and no redundant description thereof will be omitted.

The light irradiation unit 3300 may be disposed on one surface (upper surface) 3210 of the blade 3200 supporting the wafer W. A seating groove in which the light irradiation unit 3300 is seated may be formed on one surface 3210 of the blade 3200. In this case, since the light irradiation unit 3300 is disposed between the blade 3200 and the wafer W, an ultraviolet light irradiation path can be transferred directly to the surface of the wafer W without passing through the blade 3200. Accordingly, the blade 3200 may not include a light-transmitting material and may be formed entirely of an opaque material. In various example embodiments, the blade 3200 may be formed in a flat shape rather than a U shape for seating the light irradiation unit 3300.

FIG. 19 is a diagram of a wafer transfer apparatus according to various example embodiments of the present inventive concepts.

Referring to FIG. 19, the wafer transfer apparatus may include a transfer arm 4100, a blade 4200 coupled to an end portion 4110 of the transfer arm 4100, and a light irradiation unit 4300 disposed on the blade 4200. The configuration of the transfer arm 4100 and the blade 4200 may be implemented in any one of the above-described example embodiments, and no redundant description thereof will be omitted.

The light irradiation unit 4300 may be built into the blade 4200. In this case, a portion of the blade 4200 disposed between one surface 4210 of the blade 3200 and the light irradiation unit 4300 may be formed of a light transmitting material, and the remaining portion thereof may be formed of a non-transmitting material. However, the present inventive concepts are not limited thereto, and the blade 4200 may be entirely formed of a light-transmitting material. In various example embodiments, the blade 3200 may be formed in a flat shape rather than a U shape in order to for the light irradiation unit 3300 to be built in.

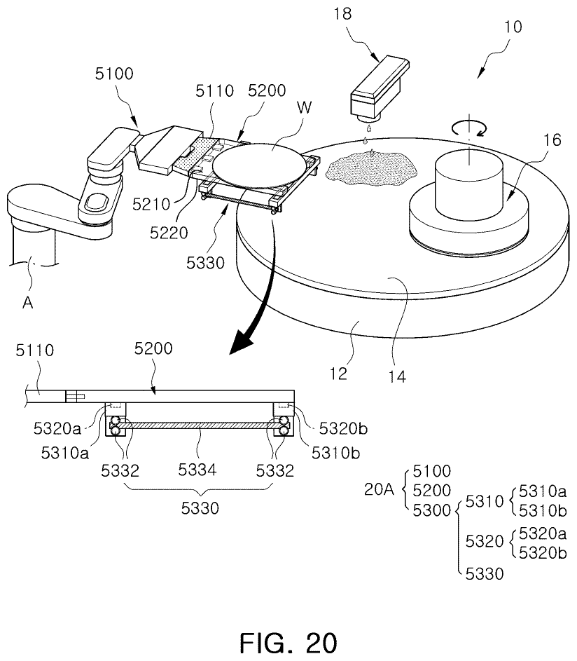

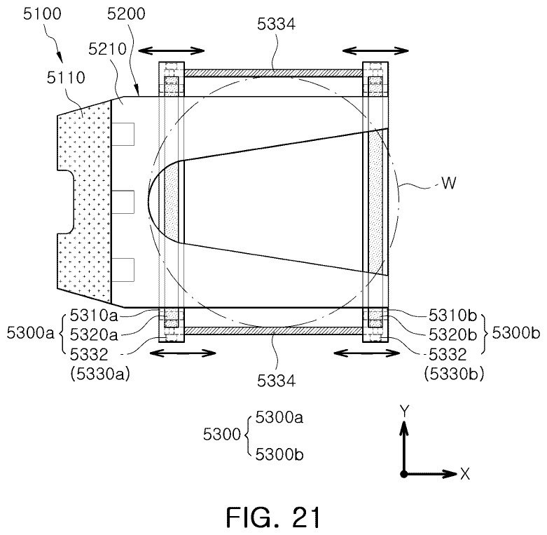

In various example embodiments as described above, the light irradiation unit has been described as being fixed to the blade, but the present inventive concepts are not limited thereto, and the light irradiation unit may be movably disposed on the blade as needed. In this regard, various example embodiments will be described below with reference to FIGS. 20 and 21.

FIG. 20 is a diagram of a wafer transfer apparatus according to various example embodiments of the present inventive concepts, and FIG. 21 is a plan view of a wafer transfer apparatus according to various example embodiments of the present inventive concepts.

Referring to FIGS. 20 and 21, the wafer transfer apparatus 20A according to various example embodiments of the present inventive concepts a transfer arm 5100, a driving unit A, a blade 5200, and a light irradiation unit 5300.

The transfer arm 5100 may transfer a wafer W to a polishing position within the polishing apparatus 10. The transfer arm 5100 may be configured in multiple stages, and may be configured to perform at least one of a lifting operation, a horizontal movement, and a rotation operation as needed. The operation of the transfer arm 5100 may be driven by the driving unit A. The driving unit A may include a driving motor, or the like.

The blade 5200 may be coupled to an end portion 5110 of the transfer arm 5100 and can support the wafer W. The blade 5200 may include one surface 5210 supporting the wafer W and the other surface 5220 opposite to the one surface 5210. A light irradiation unit 5300 irradiating ultraviolet light toward the wafer W may be disposed below the blade 5200.

The light irradiation unit 5300 may irradiate ultraviolet light toward the wafer W before the wafer W is positioned at a polishing position of the polishing apparatus 10. In various example embodiments, the light irradiation unit 5300 may irradiate ultraviolet light toward the wafer W while the wafer W is being transferred to the polishing position of the polishing apparatus 10 by the transfer arm 5100. Accordingly, hydrophilic treatment on a surface of the wafer W may be enhanced by oxidizing or curing the surface of the wafer W by irradiating ultraviolet light before polishing the surface of the wafer W. A polishing speed may be effectively improved when polishing the surface of the wafer W with the enhanced hydrophilic treatment. For example, the polishing speed may be effectively improved when polishing a carbon-based hydrophobic film.

In various example embodiments, the light irradiation unit 5300 may be movably disposed on the other surface 5220 of the blade 5200. The light irradiation unit 5300 may be configured to cover a portion of the surface of the wafer W rather than the entire surface. In this case, the light irradiation unit 5300 may irradiate ultraviolet light toward the entire region of the wafer W in a scanning manner while moving in a certain direction from the other surface 5220 of the blade 5200. In this case, the blade 5200 may have at least a portion of a light transmitting region through which ultraviolet light irradiated by the light irradiation unit 5300 passes. In various example embodiments, the light transmitting region of the blade 5200 may be configured so that an irradiation area of ultraviolet irradiated by the light irradiation unit 5300 is the same as the size of the wafer W or larger than the size of the wafer W, so as to cover the entire surface of the wafer W. The blade 5200 may be entirely formed of a light-transmitting material. As an example, the blade 5200 may include one of acrylic polymer, silicon polymer, quartz, and fumed silica. However, example embodiments are not limited thereto.

In various example embodiments, referring to FIGS. 20 and 21, the light irradiation unit 5300 may include a main body 5310 disposed on the other surface 5220 of the blade 5200, two ultraviolet light-emitting diode lamps 5320 disposed on the main body 5310, and a moving member 5330 for moving the ultraviolet light-emitting diode lamp 5320. The main body 5310 may be movably disposed on one side of the other surface of the blade 5200 in a horizontal direction. For example, as shown in FIG. 21, the blade 5200 may be movably disposed in the first direction (X). The ultraviolet light-emitting diode lamp 5320 may be disposed in various forms within the main body 5310. In various example embodiments, the ultraviolet light-emitting diode lamp 5320 may extend in the second direction (Y) of the blade 5200. In this case, the ultraviolet light-emitting diode lamp 5320 may be configured so that an extension length extending in the second direction (Y) of the blade 5200 is equal to or greater than a diameter of the wafer W. The moving member 5330 is not particularly limited as long as it can move the ultraviolet light-emitting diode lamp 5320 in the horizontal direction, and may be implemented as a moving member having various forms. In various example embodiments, the moving member 5330 may include a driving wheel 5332 connected to a motor (not shown) and a guide rail 5334 extending from a lower portion of the blade 5200 in the first direction and on which the driving wheel 5332 is disposed. As the driving wheel 5332 is rotated by a motor and moves along the guide rail 5334, the main body and the ultraviolet light-emitting diode may be moved in the first direction (X) of the blade 5200.

In various example embodiments, the light irradiation unit 5300 may include a plurality of ultraviolet light-emitting diode lamps 5320. As shown in FIGS. 20 and 21, the light irradiation unit 5300 may include a first light irradiation unit 5300a and a second light irradiation unit 5300b respectively disposed on both sides of the blade 5200 disposed at the end portion 5110 of the transfer arm 5100. The first light irradiation unit 5300a may include a first main body 5310a movably disposed on one side of the other surface 5220 of the blade 5200 in a horizontal direction, a first ultraviolet light-emitting diode lamp 5320a disposed in the first main body 5310a, and a first moving member 5330a moving the first main body 5310a. As an example, the first main body 5310a may be movably disposed in the first direction (X) of the blade 5200 on one side of the other surface 5220 of the blade 5200. The second light irradiation unit 5300b may include a second main body 5310b movably disposed on the other side of the other surface 5220 of the blade 5200 in the horizontal direction, opposite to the one side, a second ultraviolet light-emitting diode lamp 5320b disposed in the second main body 5310b, and a second moving member 5330b moving the second main body 5310b. As an example, the second main body 5310b may movably disposed in the first direction (X) of the blade 5200 on the other side of the other surface 5220 of the blade 5200. As an example, the second main body 5310b may movably disposed in the first direction (X) of the blade 5200 on the other side of the other surface 5220 of the blade 5200. The first main body 5310a and the second main body 5310b may be configured to move in opposite directions or in the same direction in the first direction (X) of the blade 5200. Accordingly, as the first ultraviolet light-emitting diode lamp 5320a and the second ultraviolet light-emitting diode lamp 5320b are movable, and ultraviolet light may be rapidly and uniformly irradiated toward the entire region of the wafer W in a scanning manner, and light irradiation efficiency to the wafer W may be improved.

However, the present inventive concepts are not limited thereto, and the light irradiation unit may include one or three or more ultraviolet light-emitting diode lamps as needed, and as a result, may be implemented in various forms as long as it can irradiate ultraviolet light to the entire region of the wafer.

For example, the light irradiation unit may include a main body on which an ultraviolet light-emitting diode lamp of a size equal to or larger than a diameter of the wafer is disposed, and a rotating member rotating the main body. In this case, the main body may rotate with a center of the wafer as a rotation center while the wafer is disposed in a correct position on the blade, and by rotating the main body, the ultraviolet light-emitting diode lamp may irradiate ultraviolet light toward the entire region of the wafer.

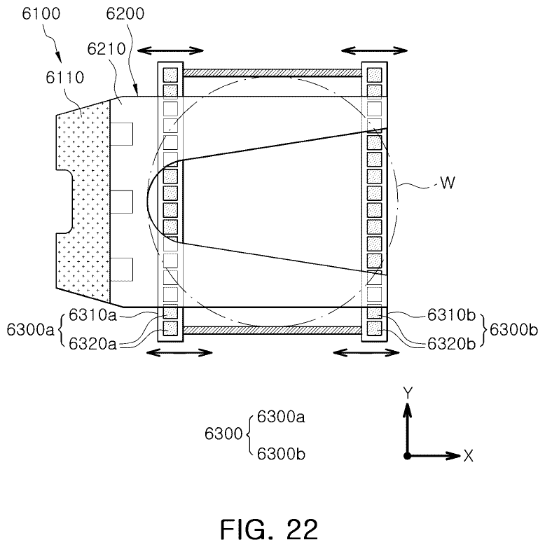

FIG. 22 is a diagram of a wafer transfer apparatus according to various example embodiments of the present inventive concepts.

Referring to FIG. 22, the light irradiation unit 6300 may include a first light irradiation unit 6300a and a second light irradiation unit 6300b respectively disposed on both sides of the blade 6200 disposed at an end portion 6110 of the transfer arm 6100. The first light irradiation unit 6300a may include a first ultraviolet light-emitting diode lamp 6320a disposed in the first main body 6310a. The first main body 6310a may be movably disposed in a first direction (X) of the blade 6200 on one side of the other surface of the blade 6200. A plurality of first ultraviolet light-emitting diode lamps 6320a may be disposed to be spaced apart from each other in a second direction (Y) of the blade 6200 within the first main body 6310a. The second light irradiation unit 6300b may include a second ultraviolet light-emitting diode lamp 6320b disposed in the second main body 6310b. The second main body 6310b may be disposed to be movable in the first direction (X) of the blade 6200 on the other side of the blade 6200. The second ultraviolet light-emitting diode lamp 6320b may be spaced apart from each other in the second direction (Y) of the blade within the second main body 6310b and disposed in plural numbers.

Meanwhile, in various example embodiments as described above, the blade has been described as an example of being configured in a U shape, but the present inventive concepts are not limited thereto, and the blade may have various forms such as an arc shape or a square shape, as needed.

In addition, in various example embodiments as described above, it has been described that the wafer transfer apparatus is applied to the polishing apparatus, but the present inventive concepts are not limited thereto, and may be applied to any apparatus requiring hydrophilic treatment on the surface of the wafer. For example, the wafer transfer apparatus of the present inventive concepts can be applied to various apparatuses such as deposition devices such as chemical vapor deposition devices, cleaning devices, photo devices, and the like, which will also fall within the scope of the present inventive concepts.

As set forth above, according to various example embodiments of the present inventive concepts, a wafer transfer apparatus that can enhance hydrophilic treatment on a surface of a wafer may be provided.

In addition, according to various example embodiments of the present inventive concepts, a wafer transfer apparatus that can improve processing efficiency of subsequent processes may be provided by enhancing hydrophilic treatment on the surface of the wafer.

The various and advantageous advantages and effects of the present inventive concepts are not limited to the above description, and may be more easily understood in the course of describing various example embodiments of the present inventive concepts.

While various example embodiments have been shown and described above, it will be apparent to those skilled in the art that modifications and variations could be made without departing from the scope of the present inventive concepts as defined by the appended claims.

What is claimed is:

1. A wafer transfer apparatus, comprising:
a transfer arm configured to transfer a wafer;
a blade coupled to an end portion of the transfer arm and configured to support the wafer; and
a light irradiation unit on the blade and configured to irradiate ultraviolet light toward the wafer.

2. The wafer transfer apparatus of claim 1, wherein the blade is configured to support the wafer on a first surface of the blade, and the light irradiation unit is on a second surface of the blade, opposite to the first surface of the blade, and
at least a portion of the blade has a light transmitting region through which ultraviolet light irradiated by the light irradiation unit is configured to pass through.

3. The wafer transfer apparatus of claim 1, wherein the blade is comprised of a light-transmitting material.

4. The wafer transfer apparatus of claim 2, wherein the blade includes at least one of acrylic polymer, silicone polymer, quartz, and fumed silica.

5. The wafer transfer apparatus of claim 1, wherein the light irradiation unit includes at least one ultraviolet light-emitting diode lamp.

6. The wafer transfer apparatus of claim 5, wherein the light irradiation unit includes a plurality of ultraviolet light-emitting diode lamps spaced apart in a first direction of the blade.

7. The wafer transfer apparatus of claim 6, wherein the plurality of ultraviolet light-emitting diode lamps respectively extend in a second direction, perpendicular to the first direction of the blade.

8. The wafer transfer apparatus of claim 5, wherein the light irradiation unit includes a plurality of ultraviolet light-emitting diode lamps spaced apart from each other in a first direction of the blade and a third direction, the third direction being different from the first direction.

9. The wafer transfer apparatus of claim 1, wherein the light irradiation unit is on one surface of the blade configured to support the wafer.

10. The wafer transfer apparatus of claim 1, wherein the light irradiation unit is in an interior of the blade.

11. The wafer transfer apparatus of claim 1, wherein the light irradiation unit has an irradiation range configured to irradiate ultraviolet light toward an entire region of the wafer.

12. The wafer transfer apparatus of claim 1, wherein the end portion of the transfer arm and one end of the blade are fitted and coupled.

13. The wafer transfer apparatus of claim 12, wherein at least one coupling protrusion is on at least one of either the end portion of the transfer arm or the one end of the blade, and at least one coupling groove into which the coupling protrusion is inserted is on the other one of either the end portion of the transfer arm or the one end of the blade.

14. The wafer transfer apparatus of claim 1, wherein a coupling portion between the end portion of the transfer arm and one end of the blade is formed in a straight or a curved shape.

15. A wafer transfer apparatus, comprising:
a transfer arm configured to transfer a wafer;
a blade coupled to an end portion of the transfer arm, the blade configured to support the wafer on a first surface of the blade, and the blade comprised of a light-transmitting material; and
a light irradiation unit on a second surface of the blade opposite to the first surface of the blade and configured to irradiate ultraviolet light toward the wafer.

16. The wafer transfer apparatus of claim 15, wherein the light irradiation unit includes a main body on a first side of the second surface of the blade in a horizontal direction, an ultraviolet light-emitting diode lamp on the main body, and a moving member configured to move the ultraviolet light-emitting diode lamp.

17. The wafer transfer apparatus of claim 15, wherein the light irradiation unit includes
a first light irradiation unit including a first main body on a first side of the second surface of the blade in a horizontal direction, a first ultraviolet light-emitting diode lamp on the first main body, and a first moving member configured to move the first main body; and
a second light irradiation unit including a second main body on a second side of the second surface of the blade, opposite to the first side, in a horizontal direction, a second ultraviolet light-emitting diode lamp on the second main body, and a second moving member configured to move the second main body.

18. The wafer transfer apparatus of claim 17, wherein the first main body and the second main body are configured to move in opposite directions or in a same direction.

19. A wafer transfer apparatus, comprising:
a transfer arm configured to transfer a wafer to a polishing position within a polishing apparatus;
a driving unit configured to drive an operation of the transfer arm;
a blade coupled to an end portion of the transfer arm and configured to support the wafer; and
a light irradiation unit on the blade and configured to irradiate ultraviolet light toward the wafer while the wafer is being transferred to the polishing position by the transfer arm.

20. The wafer transfer apparatus of claim 19, wherein the light irradiation unit is configured to have a fixed position or a movable position on the blade.
